(19) United States
(12) Patent Application Publication
(10) Pub. No.: US 2006/0215467 A1
(43) Pub. Date: Sep. 28, 2006

(54) Method of increasing data setup and hold margin in case of non-symmetrical PVT

(76) Inventor: Torsten Partsch, Raleigh, NC (US)

Correspondence Address: PATTERSON & SHERIDAN, LLP;Gero McClellan / Infineon Technologies, 3040 POST OAK BLVD.,, SUITE 1500, HOUSTON, TX, 77056, US

(21) Appl. No.: 11/087,182

(22) Filed: Mar. 22, 2005

(51) Int. Cl. G11C 7/00

(52) U.S. Cl. 365/194

(57) ABSTRACT

Techniques and apparatus to reduce duty cycle distortion in DRAM devices caused by process variations are provided. By dividing the undelayed output signal from the data receivers into two separate paths and providing independently adjustable delay blocks in each path leading to the rising and falling edge data latches, the setup and/or hold timing margins may be adjusted.

### BACKGROUND OF THE INVENTION

1. Field of the Invention

The invention generally relates to memory devices and, more particularly to adjusting delay blocks to compensate for process variations.

2. Description of the Related Art

The evolution of sub-micron CMOS technology has resulted in an increasing demand for high-speed semiconductor memory devices, such as dynamic random access memory (DRAM) devices, pseudo static random access memory (PSRAM) devices, and the like. Herein, such memory devices are collectively referred to as DRAM devices.

Some types of DRAM devices have a synchronous interface, generally meaning that data is written to and read from the devices in conjunction with a clock pulse (e.g., a data strobe signal DQS). Early synchronous DRAM (SDRAM) devices transferred a single bit of data per clock cycle (e.g., on a rising edge) and are appropriately referred to as single data rate (SDR) SDRAM devices. Later developed double-data rate (DDR) SDRAM devices include input/output (I/O) buffers that latch a bit of data on both rising and falling edges of the clock signal, thereby doubling the effective data transfer rate.

As illustrated in FIG. 1, data signals (DQ[0:N]) presented on pads 102 may be received by identical receive and latch blocks 110. The data strobe signal (DQS) presented on a pad 102 is received by a DQS receive and drive block 120. The drive block 120 includes a receive circuit 122 and drive circuit 124 that drives the DQS signal to the receive and latch blocks 110.

As illustrated, the receive and latch blocks 110 receive the data signals with receiver circuits 112. The output of these receiver circuits 112 is then delayed (DEL) via a delay circuit 114 to match the delay that is needed for the internal DQS signal to be driven to the individual receive and latch blocks 110 from the DQS receive and drive block 120. The delay on the DQS signal results from both RC delay of the routing wires and transition delay of the driver block 120.

After the delay block 114, the data signal (DIN) path is split and routed to two latch blocks: a master-slave Flip Flop (MS-FF) latch 116 which retains the data sent on the falling edge of DQS, and a master-slave-slave Flip Flop (MSS-FF) latch 118 that retains the data sent on the rising edge of DQS. The input stages of both of these latches 116 and 118 need sufficient setup and hold time to operate correctly.

As used herein, setup time generally refers to the amount of time a data signal should be stable before a corresponding data strobe signal edge, while hold time generally refers the amount of time a data signal should be stable after the corresponding strobe signal edge. FIG. 2 is a timing diagram of signals illustrating setup and hold timing at the two latches 116 and 118.

In FIG. 2, two different data patterns are shown to illustrate the impact of imbalanced effects of process variations on setup and hold timing. A first data pattern P1 has logical high data sent on the rising edge of the strobe signal and logical low data sent on the falling edge of the strobe signal. A second data pattern P2 has logical low data sent on the rising edge of the strobe signal and logical high data sent on the falling edge of the strobe signal. In other words, data pattern P1 corresponds to a LO-HI (0-1) sequence, while data pattern P2 corresponds to a HI-LO (1-0) sequence.

The first (top) signal diagram 200 illustrates the relationship of signals P1 and P2 to DQS assuming ideal timing conditions, with no variations in rising and falling switching times due to process variations and, hence, no duty cycle distortion. In other words, the rising edge of the ideal signal P1 (DIN_ID_P1) switches at the same time as the falling edge of the ideal signal P2 (DIN_ID_P2). Further, the ideal DQS signal (DQS_ID) switches roughly in the middle of the transitions, providing ample setup times (tSRM and tSFM) and hold times (tHRM and tHFM) for each data signal.

Unfortunately, as DDR SDRAMS are run at increasingly higher frequencies and lower supply voltages, shrinking cycle times allow less for time for data setup and hold. Further, as the operating frequencies increase, the processes with which these devices are built continue to shrink the feature size. With decreasing feature size, process, voltage and temperature (PVT) deviations resulting in duty cycle distortion (e.g., due to differences in P and N type processes) become more pronounced. One of the effects of PVT deviations is that the propagation delays of signal edges though receivers, logic blocks and delay lines vary. If the delay for rising and failing edges is affected differently from the PVT variations, the duty cycle is distorted. In most DRAM processes, these distortions do not affect both edges symmetrically, meaning that the difference between “slowest and fastest” rising edge is not the same as the difference between the “slowest and fastest” falling edge.

This is illustrated in the second (middle) signal diagram 210 which shows the relationship of signals P1 and P2 to DQS assuming non-ideal timing conditions due to process variations that favor rising edge signals. As illustrated, the rising edge of signal P1 (DIN_HI_P1) in this case switches before the falling edge of the signal P2 (DIN_HI_P2). As illustrated, the delayed switching point of the falling edge of the signal P2 results in reduced setup timing margins (e.g., tSRM is reduced by tDIS1). Further, assuming the switching point of the falling edge of DQS will be delayed in a similar manner, hold timing margins for the low portion of P1 prior to the subsequent rising edge of P1 (tHFM) is also reduced. While these margins may be acceptable in the example, in other cases the margins due to imbalance may be too narrow.

For example, the third (bottom) signal diagram 220 illustrates the relationship of signals P1 and P2 to DQS assuming non-ideal timing conditions due to process variations that favor falling edge signals. As illustrated, the delayed switching of the rising edge of the DQS signal results in insufficient hold timing margins (tHRM) before the falling edge of P1 (DIN_LO_P1). Further, assuming the rising edge of P2 (DIN_LO_P2) will be delayed in a similar manner, setup timing margins (tSFM) for the rising edge of P2 prior to the falling edge of DQS may also be insufficient.

The conventional approach to increase setup and hold margins is to increase the resolution of the receiver block. Using this approach, signal changes on the input of the receiver may be detected faster which may serve to limit duty cycle distortion. However, disadvantages to this approach include higher power consumption and larger area needed for the receiver blocks. Particularly for low power derivates of DDR SDRAMs (e.g., Mobile DDR SDRAMs), power consumption of the data and DQS receiver blocks is critical.

Accordingly, a need exists for improved techniques and apparatus to reduce duty cycle distortion in DRAM devices caused by process variations.

### SUMMARY OF THE INVENTION

Embodiments of the invention generally provide techniques and apparatus to reduce duty cycle distortion in DRAM devices caused by process variations.

One embodiment provides a memory device generally including a plurality of data pads for receiving data signals transmitted on rising and falling edges of an externally supplied data strobe signal and, for each data pad, a receive and latch circuit. Each receive and latch circuit has a receiver circuit to receive data signals provided on the data pad, a first delay element in a signal path between the receiver circuit and a first latch circuit to delay, by a first delay amount, a first data signal latched by the first latch circuit on a rising edge of the data strobe signal, and a second delay element in a signal path between the receiver circuit and a second latch circuit to delay, by a second delay amount, a second data signal latched by the second latch circuit on a rising edge of the data strobe signal.

Another embodiment provides a double data rate (DDR) dynamic random access memory (DRAM) device. The device generally includes a plurality of data pads for receiving data signals transmitted on rising and falling edges of an externally supplied data strobe signal and, for each data pad, a receive and latch circuit. Each receive and latch circuit generally includes a receiver circuit to receive data signals provided on the data pad, a first latch circuit to latch a first data signal received by the receiver circuit in conjunction with a rising edge of the data strobe signal, a second latch circuit to latch a second data signal received by the receiver circuit in conjunction with a falling edge of the data strobe signal, a first delay element in a signal path between the receiver circuit and the first latch circuit to delay the first data signal by a first delay amount, and a second delay element in a signal path between the receiver circuit and the second latch circuit to delay the second data signal by a second delay amount, wherein the first and second delay amounts are independently adjustable.

Another embodiment provides a receive and latch circuit. The receive and latch circuit generally includes a receiver circuit to receive data signals provided on a data pad, a first latch circuit to latch a first data signal received by the receiver circuit in conjunction with a rising edge of a data strobe signal, a second latch circuit to latch a second data signal received by the receiver circuit in conjunction with a falling edge of the data strobe signal, a first delay element in a signal path between the receiver circuit and the first latch circuit to delay the first data signal by a first delay amount, and a second delay element in a signal path between the receiver circuit and the second latch circuit to delay the second data signal by a second delay amount, wherein the first and second delay amounts are independently adjustable.

Another embodiment provides a method for adjusting setup and hold data sampling times in a memory device for process variations. The method generally includes receiving a data strobe signal, delaying a first data signal sent in conjunction with a rising edge of the data strobe signal by a first delay amount, delaying a second data signal sent in conjunction with a falling edge of the data strobe signal by a second delay amount independent of the first delay amount, and latching the first and second data signals with first and second latch circuits triggered, respectively, on rising and falling edges of the data strobe signal.

Another embodiment provides a method of manufacturing a memory device. The method generally includes fabricating the memory device having a plurality of data pads for receiving data signals transmitted on rising and falling edges of an externally supplied data strobe signal and, for each data pad, a receive and latch circuit having a first latch to latch a first data signal received by the receiver circuit on a rising edge of the data strobe signal and a second latch to latch a second signal received by the receiver circuit, performing one or more tests to determine effects of process variations on setup and hold times of data signals relative to the data strobe signal, and based on results of the one or more tests, adjusting a first delay element in a signal path between the receiver circuit and a first latch circuit and a second delay element in a signal path between the receiver circuit and a second latch circuit.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a conventional data receive and latch block;

FIG. 2 illustrates timing diagrams for data and data strobe signals involved in the data receive and latch block of FIG. 1;

FIG. 3 illustrates a data receive and latch block in accordance with one embodiment of the present invention; and

FIG. 4 illustrates timing diagrams for data and data strobe signals involved in the data receive and latch block of FIG. 3.

### DETAILED DESCRIPTION OF THE PREFERRED EMBODIMENT

Embodiments of the invention generally provide techniques and apparatus to reduce duty cycle distortion in DRAM devices, for example, caused by process variations. By dividing the undelayed output signal from the data receivers into two separate paths and providing independently adjustable delay blocks in each path leading to the rising and falling edge data latches, the setup and hold timing margins may be increased.

Embodiments of the present invention are described below with reference to double data rate (DDR) DRAM devices in which two bits of data are exchanged on each data pad in each clock cycle (i.e., on rising and falling edges). Those skilled in the art will appreciate, however, that the concepts described herein may be applied to virtually any device where data is transferred synchronously (e.g., on both edges of a clock). For example, the concepts described herein may also be applied to advantage to adjust timing margins in devices in which more than two bits of data are exchanged on each data pad in each clock cycle, such as DDR-II and DDR-III type DRAM devices.

### Exemplary Receive and Latch Blocks

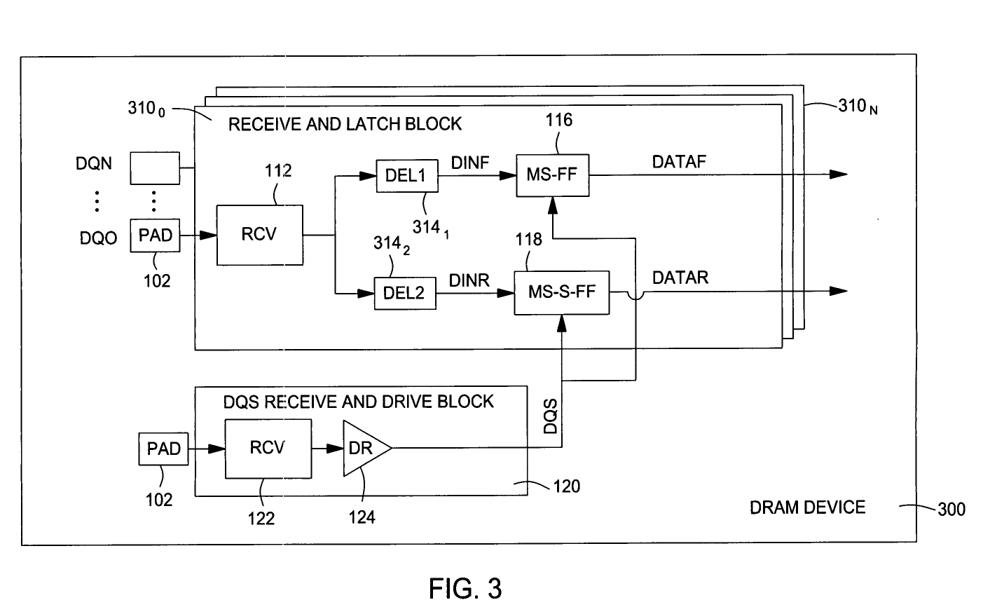

FIG. 3 illustrates data receive and latch blocks 310 in accordance with one embodiment of the present invention. As illustrated, data signals (DQ[0:N]) presented on pads 102 are received by the latch blocks 310, while data strobe signal (DQS) presented on a pad 102 is received by a DQS receive and drive block 120. As previously described, the drive block 120 includes a receive circuit 122 and drive circuit 124 that drives the DQS signal to the receive and latch blocks 310.

As illustrated, the receive and latch blocks 310 receive the data signals with receiver circuits 112. The output signal from the receiver circuit 112 is then divided into two paths that lead to separate delay elements 314₁ and 314₂. After the delay elements 314₁ and 314₂, the data signal path is split (DINF and DINR) and routed to two latch blocks: a master-slave Flip Flop (MS-FF) latch 116 which retains the data sent with the falling edge of DQS, and a master-slave-slave Flip Flop (MSS-FF) latch 118 that retains the data sent on the rising edge of DQS.

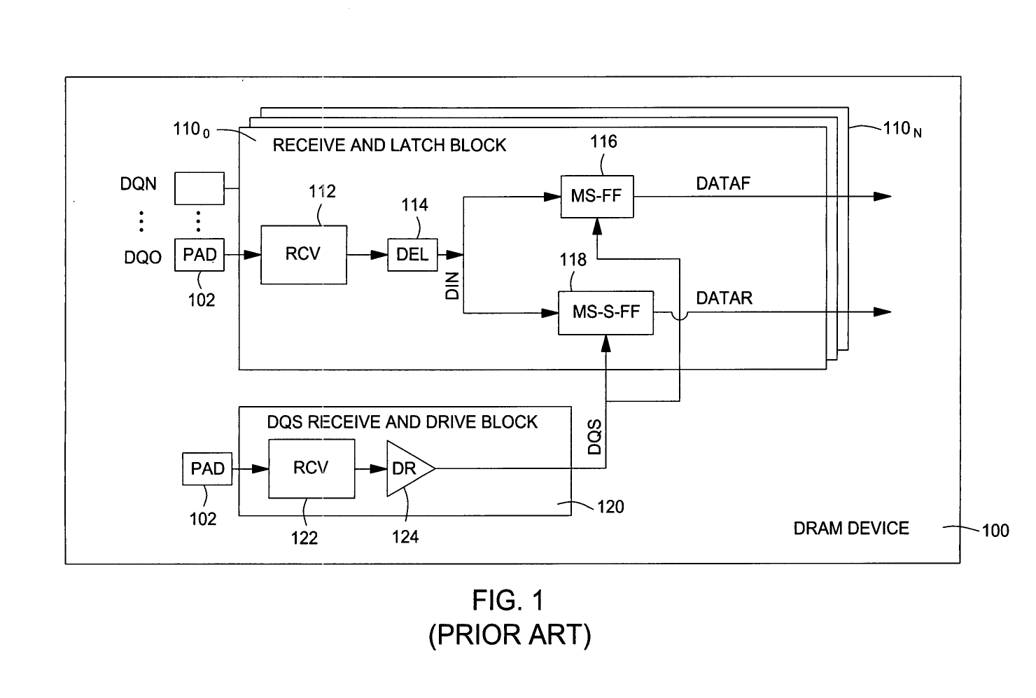

As previously described, the input stages of both of these latches 116 and 118 need sufficient setup and hold time to operate correctly. Process variations may result in duty cycle distortion that serves to reduce setup and hold times in conventional devices. However, according to embodiments of the present invention, the delay elements 314₁ and 314₂ may be independently adjusted to delay the data signals transmitted on falling and rising edges of DQS, respectively, to compensate for process variations and increase previously marginal setup and hold times. The separate delay elements 314₁ and 314₂ may provide a greater degree of flexibility to adjust timing margins than the single delay element (114 of FIG. 1) of conventional designs.

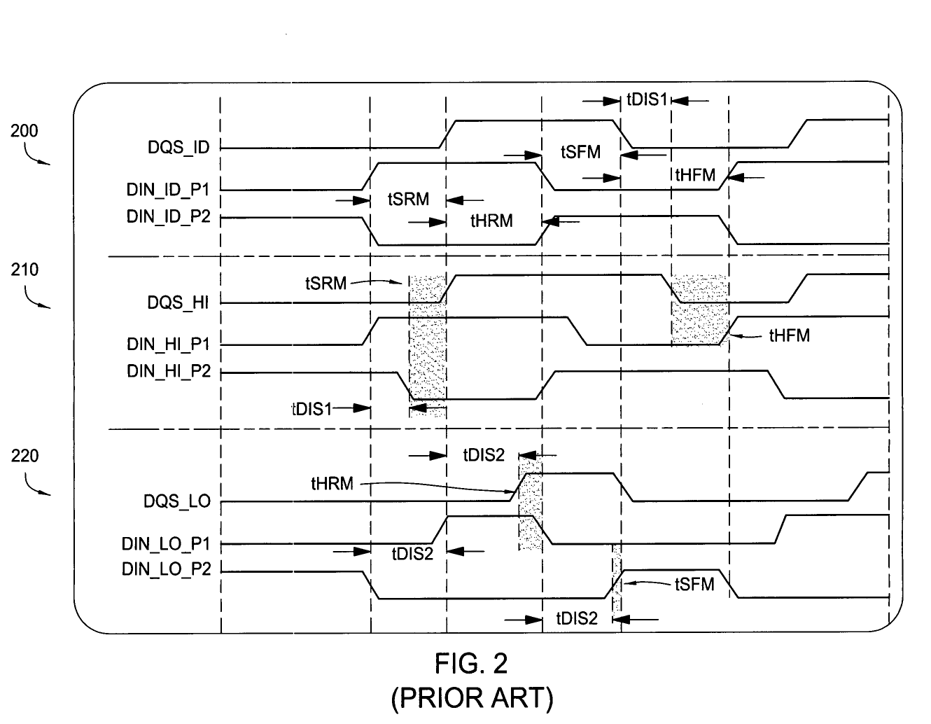

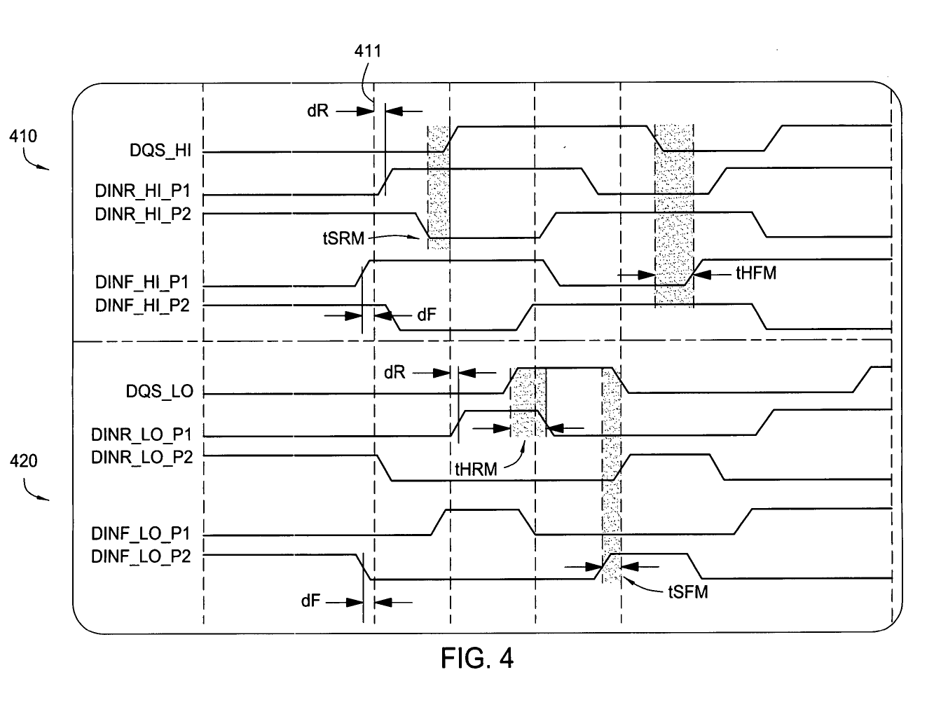

In other words, the separate delay elements 314₁ and 314₂ may be adjusted in an effort to provide an optimal balance between timing margins for sampling data transmitted on rising and falling edges of the DQS signal over the expected range of operating parameters. As described with reference to the exemplary timing diagram of FIG. 2, sufficiently large timing margins (e.g., tSRM and tHFM) were achieved in the case of process variations favoring rising edges, but significantly shorter timing margins (tHRM and tSFM) were achieved in the case of process variations favoring falling edges. As illustrated in FIG. 4, however, by independently adjusting the delay elements 314₁ and 314₂, these timing margins may be adjusted to increase the previously marginal hold and setup times (tHRM and tSFM).

FIG. 4 is a timing diagram of signals illustrating the effect of delay elements 314₁ and 3142 on setup and hold timing at the two latches 116 and 118. As with FIG. 2 described above, to illustrate the impact of imbalanced effects due to process variations, FIG. 4 shows two data patterns P1 and P2. P1 has logical high data sent on the rising edge of the strobe signal and logical low data sent on the falling edge of the strobe signal, while P2 has logical low data sent on the rising edge of the strobe signal and logical low data sent on the falling edge of the strobe signal. As previously described, data pattern P1 corresponds to a LO-HI (0-1) sequence, while data pattern P2 corresponds to a HI-LO (1-0) sequence. In FIG. 4, however, separate signals for the data patterns are shown after the delay blocks 314, and 3142 (denoted as DINF_and DINR_, respectively) to illustrate the impact of the delay elements on timing margins.

Referring first to the upper timing diagram 410 corresponding to the case where process variations result in faster switching for rising edges, signals DINR_HI_P1 and DINR_HI_P2 represent signals for the different data patterns after they pass through the second delay block 314₂, while signals DINF_HI_P1 and DINF_HI_P2 represent signals after they pass through the first delay block 314₁. Labels dF and dR indicate the relative changes to the signals due to delay elements 314₁ and 314₂, respectively, relative to a baseline transition point 411 that would occur if the delay elements 314₁ and 314₂ were set to cause equal durations of delays of the signals.

In the illustrated example, delay elements 314₁ and 314₂ are adjusted such that dR is greater than dF (relative to the baseline 411), so data signals latched in on the rising edge of DQS are delayed relative to data signals latched in on the falling edge of DQS. This particular delay setting has the effect of shifting the data signals latched in on the rising edge of DQS to the right of the baseline 411 while shifting the data signals latched in on the falling edge of DQS to the left of the baseline 411. In other words, the delay elements 314, and 3142 introduce relatively less delay (dF) and relatively more delay (dR), respectively.

This can be seen by comparing the timing diagram 410 of FIG. 4 to the timing diagram 210 shown in FIG. 2. In diagram 410, the signals latched on the rising edge of DQS (DINR_HI_P1 and DINR_HI_P2) are delayed by dR, while the signals latched on the falling edge of DQS (DINF_HI_P1 and DINF_HI_P2) are, in effect, sped up by dF (i.e., the signals are less delayed relative to the baseline 411). This “speeding up” may be possible by reducing a default delay that results in sooner switching relative to the baseline switching point 411. While this has the effect of reducing corresponding setup and hold times (tSRM and tHFM) relative to that shown in diagram 210 of FIG. 2, these timing margins are still sufficient.

In the case of process variations that favor falling edges, however, adjusting the delay elements 314₁ and 314₂ in this manner results in significant increases in timing margins that were previously marginal (e.g., tHRM and tSFM shown in diagram 220 of FIG. 2). As illustrated in the timing diagram 420, while the rising edge of DQS is delayed in this case, the corresponding delay in transition to the falling edge of data latched in on the rising edge of DQS (DINR_LO_P1) results in an increased in corresponding hold time (tHRM). Similarly, while the falling edge of DQS comes sooner in this case, because the transition to the rising edge of data latched in on the falling edge of DQS (DINF_LO_P2) happens sooner (by dF), corresponding setup time (tSFM) is increased.

Of course, those skilled in the art will recognize that there may be cases where increasing the delay of data latched in on falling edges (dF>dR) may result in more optimal timing margins. In any case, by providing independently adjustable delay elements in separate signal paths of data latched in on rising and falling edges of DQS, sufficient timing margins over a wide range of parameter variations may be achieved. This approach is particularly advantageous when variations in timing margins are not symmetrical over an expected range of process, voltage, and temperature (PVT) variations, which is typically the case. For example, the separate delay elements allow compensation when process variations result in setup timing margins for data latched on the rising edge (tSRM) that are significantly different than setup timing margins for data latched on the falling edge (tSFM). If the variations in timing margins are symmetrical, adequate adjustments may be made with a single delay element, as in conventional designs.

### Setting The Delays

In some cases, in order to determine the proper delay settings, empirical testing over an expected range of operating parameters may be performed. The testing may be performed on an actual device (e.g., by reading and writing data patterns) or via computer simulations. Through this testing, variations in timing margins may be recorded and noted. Appropriate individual delay settings of delay elements 314₁ and 314₂ may then be selected. In some cases, testing may be repeated using the selected delay settings to verify adequate timing margins are achieved even in worst cases.

Exactly how the delays are set may depend on how the exact implementation of the delay elements 314₁ and 314₂. For example, for some embodiments, a certain metal layer may be provided that allows connections to be selectively made/broken to connect/dis-connect delay elements in a delay chain. The delay elements may be, for example, inverter pairs that are connected in series to build the delay chain or capacitors (connected in parallel) that have to be charged or discharged. In any case, because these changes to select/disconnect delay elements effect only a single metal layer, the cost to reconfigure (or select) a mask set to achieve an optimum balance in delay between rising and falling data signal paths may be relatively inexpensive. Further, because the metal layers are typically processed late during the production cycle, the impact on processing time (turnaround time) due to a change in masks may be relatively small.

For other embodiments, the delay associated with each of the delay elements may be set by altering the state of one or more fuses (e.g., blowing laser fuses during manufacturer, or blowing electrically programmable fuses, altering anti-fuses, and the like). The different fuses may, for example, be used to route a signal path through one or more delay elements to control the delay for a particular delay element.

For still other embodiments, the delay associated with each of the delay elements may be dynamically adjusted during operation of the device (i.e, “soft set”) by writing to one or more control registers on the device. For example, for some embodiments the delay elements may be actively adjusted, for example, based on a temperature measurement taken from a temperature sensor near a device.

### CONCLUSION

By dividing the undelayed output signal from data receivers into separate paths and creating independently adjustable delay blocks in each path leading to rising and falling edge data latches, setup and/or hold timing margins may be adjusted (e.g., increased).

While the foregoing is directed to embodiments of the present invention, other and further embodiments of the invention may be devised without departing from the basic scope thereof, and the scope thereof is determined by the claims that follow.

What is claimed is:

1. A memory device, comprising:
a plurality of data pads for receiving data signals transmitted on rising and falling edges of an externally supplied data strobe signal; and
for each data pad, a receive and latch circuit having a receiver circuit to receive data signals provided on the data pad, a first delay element in a signal path between the receiver circuit and a first latch circuit to delay, by a first delay amount, a first data signal latched by the first latch circuit on a rising edge of the data strobe signal, and a second delay element in a signal path between the receiver circuit and a second latch circuit to delay, by a second delay amount, a second data signal latched by the second latch circuit on a rising edge of the data strobe signal.

2. The memory device of claim 1, wherein the first and second delay amounts are independently adjustable during manufacturing of the device.

3. The memory device of claim 3, wherein the first and second delay amounts are independently adjustable during manufacturing of the device by altering connections made via one or more metal layers of components forming the first and second delay elements.

4. The memory device of claim 1, wherein the first and second delay amounts are independently and dynamically adjustable during operation of the device.

5. The memory device of claim 1, wherein the first and second delay amounts are independently adjustable by altering the state one or more fuses.

6. A double data rate (DDR) dynamic random access memory (DRAM) device, comprising:
a plurality of data pads for receiving data signals transmitted on rising and falling edges of an externally supplied data strobe signal; and
for each data pad, a receive and latch circuit having,
a receiver circuit to receive data signals provided on the data pad,
a first latch circuit to latch a first data signal received by the receiver circuit in conjunction with a rising edge of the data strobe signal,
a second latch circuit to latch a second data signal received by the receiver circuit in conjunction with a falling edge of the data strobe signal,
a first delay element in a signal path between the receiver circuit and the first latch circuit to delay the first data signal by a first delay amount, and
a second delay element in a signal path between the receiver circuit and the second latch circuit to delay the second data signal by a second delay amount, wherein the first and second delay amounts are independently adjustable.

7. The memory device of claim 6, wherein the first and second delay amounts are independently adjustable during manufacture of the device by manipulating one or more metal layers used to connect circuit components of the first and second delay elements.

8. The memory device of claim 6, wherein the first and second delay amounts are independently and dynamically adjustable during operation of the device.

9. The memory device of claim 6, wherein the first and second delay amounts are independently adjustable by altering the state one or more fuses.

10. A receive and latch circuit, comprising:
a receiver circuit to receive data signals provided on a data pad;
a first latch circuit to latch a first data signal received by the receiver circuit in conjunction with a rising edge of a data strobe signal;
a second latch circuit to latch a second data signal received by the receiver circuit in conjunction with a falling edge of the data strobe signal;
a first delay element in a signal path between the receiver circuit and the first latch circuit to delay the first data signal by a first delay amount; and
a second delay element in a signal path between the receiver circuit and the second latch circuit to delay the second data signal by a second delay amount, wherein the first and second delay amounts are independently adjustable.

11. A method for adjusting setup and hold data sampling times in a memory device for process variations, comprising:
receiving a data strobe signal;
delaying a first data signal sent in conjunction with a rising edge of the data strobe signal by a first delay amount;
delaying a second data signal sent in conjunction with a falling edge of the data strobe signal by a second delay amount independent of the first delay amount; and
latching the first and second data signals with first and second latch circuits triggered, respectively, on rising and falling edges of the data strobe signal.

12. The method of claim 11, wherein the first delay amount is greater than the second delay amount.

13. The method of claim 11, further comprising, adjusting at least one of the first and second delay amounts during operation of the device.

14. The method of claim 13, wherein adjusting at least one of the first and second delay amounts comprises adjusting a value in a control register.

15. A method of manufacturing a memory device, comprising:
fabricating the memory device having a plurality of data pads for receiving data signals transmitted on rising and falling edges of an externally supplied data strobe signal and, for each data pad, a receive and latch circuit having a first latch to latch a first data signal received by the receiver circuit on a rising edge of the data strobe signal and a second latch to latch a second signal received by the receiver circuit;
performing one or more tests to determine effects of process variations on setup and hold times of data signals relative to the data strobe signal; and
based on results of the one or more tests, adjusting a first delay element in a signal path between the receiver circuit and a first latch circuit and a second delay element in a signal path between the receiver circuit and a second latch circuit.

16. The method of claim 15, wherein performing the one or more tests comprises performing one or more computer simulations.

17. The method of claim 15, wherein performing the one or more tests comprises performing one or more tests on the fabricated device.

18. The method of claim 15, wherein adjusting the first and second delay elements comprises selecting a mask for use during fabrication of the device that affects connection made via one or more metal layers of one or more components of the first and second delay elements.

19. The method of claim 15, wherein adjusting the first and second delay elements comprises altering the state of one or more fuses.

20. The method of claim 15, wherein adjusting the first and second delay elements comprises writing to one or more control registers.

21. A receive and latch circuit, comprising:
means for receiving data signals provided on a data pad;
means for latching a first data signal received by the means for receiving in conjunction with a rising edge of a data strobe signal;
means for latching a second data signal received by the means for receiving in conjunction with a falling edge of the data strobe signal;
in a signal path between the means for receiving and the means for latching the first data signal, means for delaying the first data signal by a first delay amount; and
in a signal path between the means for receiving and the means for latching the second data signal, means for delaying the second data signal by a second delay amount, wherein the first and second delay amounts are independently adjustable.
